(19) United States
(12) Patent Application Publication
(10) Pub. No.: US 2026/0291177 A1
(43) Pub. Date: Sep. 24, 2026

(54) LIGHT-EMITTING DEVICE

(71) Applicant: FUJIFILM Business Innovation Corp., Tokyo (JP)

(72) Inventor: Tomoaki SAKITA, Kanagawa (JP)

(73) Assignee: FUJIFILM Business Innovation Corp., Tokyo (JP)

(21) Appl. No.: 19/288,760

(22) Filed: Aug. 1, 2025

(30) Foreign Application Priority Data
Mar. 18, 2025 (JP) 2025-043472

(51) Int. Cl. H01S 5/042; H01S 5/42

(52) U.S. Cl. CPC H01S 5/0428; H01S 5/423

(57) ABSTRACT

A light-emitting device includes: a light-emitting unit including multiple light-emitting elements; a drive circuit that serves to drive the multiple light-emitting elements and includes multiple first transistors each provided between cathode electrodes of the multiple light-emitting elements and a ground potential, multiple second transistors each provided between anode electrodes of the multiple light-emitting elements and the cathode electrodes of the multiple light-emitting elements, and a third transistor that serves to cause a current to flow through the multiple light-emitting elements to allow the multiple light-emitting elements to emit light as a result of the third transistor being turned ON; and a controller that selects at least one light-emitting element which is caused to emit light among the multiple light-emitting elements so as to switch between the multiple light-emitting elements and causes the third transistor to be ON for a predetermined period so that the selected at least one light-emitting element emits light, and that controls the drive circuit so that at least one first transistor of the multiple first transistors is turned ON at a timing when the selected at least one light-emitting element starts emitting light, the number of the at least one first transistor being determined in accordance with the number of the selected at least one light-emitting element which is to simultaneously emit light, and/or so that at least one second transistor of the multiple second transistors is turned ON at a timing when the selected at least one light-emitting element stops emitting light, the number of the at least one second transistor being determined in accordance with the number of the selected at least one light-emitting element which is to simultaneously emit light. The controller controls the drive circuit so that, as the number of the selected at least one light-emitting element which is to simultaneously emit light is greater, the number of the at least one first transistor to be turned ON becomes smaller and the number of the at least one second transistor to be turned ON becomes smaller.

### CROSS-REFERENCE TO RELATED APPLICATIONS

This application is based on and claims priority under 35 USC 119 from Japanese Patent Application No. 2025-043472 filed Mar. 18, 2025.

### BACKGROUND

### (i) Technical Field

The present disclosure relates to a light-emitting device.

### (ii) Related Art

Japanese Unexamined Patent Application Publication No. 2023-113029 discloses a distance measurement device that can drive light-emitting elements in multiple regions independently from each other.

### SUMMARY

A light-emitting device including a light-emitting unit, such as a vertical cavity surface emitting laser (VCSEL), having multiple light-emitting elements, that can perform control to allow only light-emitting elements selected from the multiple light-emitting elements to emit light is known. In this type of light-emitting device, the number of light-emitting elements to simultaneously emit light is varied in accordance with the situation where the light-emitting device is used.

Regardless of the number of light-emitting elements to simultaneously emit light, parasitic capacitance is generated in the light-emitting unit. Each of the light-emitting elements has series resistance, and the combined resistance of the individual series resistance values is different depending on the number of light-emitting elements to simultaneously emit light. It is desirable to control the light emission of the light-emitting elements so that the amount of light emission becomes uniform during a specified light-emission period. That is, a light pulse waveform, which is the waveform of a light-emission current to flow when a light-emitting element emits light is desirably a rectangular waveform. However, due to a CR circuit constituted by the parasitic capacitance generated in the light-emitting unit and the combined resistance, which is varied in accordance with the number of light-emitting elements to simultaneously emit light, waveform rounding occurs at the rising and the falling of the waveform of a light pulse wave to be applied to a light-emitting element to emit light. That is, the light pulse waveform deviates from the rectangular waveform.

Aspects of non-limiting embodiments of the present disclosure relate to a light-emitting device that can perform control so that the waveform of a light pulse wave to be applied to a light-emitting element which is to emit light is made similar to a rectangular waveform even when the number of light-emitting elements to simultaneously emit light is changed, compared with the configuration in which the number of transistors forming a drive circuit is not switched in accordance with the number of light-emitting elements to simultaneously emit light.

Aspects of certain non-limiting embodiments of the present disclosure address the above advantages and/or other advantages not described above. However, aspects of the non-limiting embodiments are not required to address the advantages described above, and aspects of the non-limiting embodiments of the present disclosure may not address advantages described above.

According to an aspect of the present disclosure, there is provided a light-emitting device including: a light-emitting unit including multiple light-emitting elements; a drive circuit that serves to drive the multiple light-emitting elements and includes multiple first transistors each provided between cathode electrodes of the multiple light-emitting elements and a ground potential, multiple second transistors each provided between anode electrodes of the multiple light-emitting elements and the cathode electrodes of the multiple light-emitting elements, and a third transistor that serves to cause a current to flow through the multiple light-emitting elements to allow the multiple light-emitting elements to emit light as a result of the third transistor being turning ON; and a controller that selects at least one light-emitting element which is caused to emit light among the multiple light-emitting elements so as to switch between the multiple light-emitting elements and causes the third transistor to be ON for a predetermined period so that the selected at least one light-emitting element emits light, and that controls the drive circuit so that at least one first transistor of the multiple first transistors is turned ON at a timing when the selected at least one light-emitting element starts emitting light, the number of the at least one first transistor being determined in accordance with the number of the selected at least one light-emitting element which is to simultaneously emit light, and/or so that at least one second transistor of the multiple second transistors is turned ON at a timing when the selected at least one light-emitting element stops emitting light, the number of the at least one second transistor being determined in accordance with the number of the selected at least one light-emitting element which is to simultaneously emit light. The controller controls the drive circuit so that, as the number of the selected at least one light-emitting element which is to simultaneously emit light is greater, the number of the at least one first transistor to be turned ON becomes smaller and the number of the at least one second transistor to be turned ON becomes smaller.

### BRIEF DESCRIPTION OF THE DRAWINGS

An exemplary embodiment of the present disclosure will be described in detail based on the following figures, wherein:

FIG. 1 is a circuit diagram illustrating the configuration of a light-emitting device according to the exemplary embodiment of the disclosure;

FIG. 2A is a circuit diagram illustrating the configuration in which light-emitting elements are all caused to emit light without the provision of a light-emission-ON-time voltage drive circuit and a light-emission-OFF-time voltage drive circuit;

FIG. 2B is a timing chart illustrating that waveform rounding occurs at the rising and the falling of the waveform of a light-emission pulse signal in the configuration shown in FIG. 2A;

FIG. 3A is a circuit diagram illustrating the configuration in which only one light-emitting element is caused to emit light without the provision of a light-emission-ON-time voltage drive circuit and a light-emission-OFF-time voltage drive circuit;

FIG. 3B is a timing chart illustrating that waveform rounding occurs at the rising and the falling of the waveform of a light-emission pulse signal in the configuration shown in FIG. 3A;

FIG. 4 is a circuit diagram illustrating the configuration in which a light-emission-ON-time voltage drive circuit and a light-emission-OFF-time voltage drive circuit are each constituted by one transistor;

FIG. 5 is a timing chart illustrating that a light pulse waveform becomes similar to a rectangular waveform by the provision of the light-emission-ON-time voltage drive circuit and the light-emission-OFF-time voltage drive circuit shown in FIG. 4;

FIG. 6 is a timing chart illustrating that a light pulse waveform deviates from a rectangular waveform by the provision of the light-emission-ON-time voltage drive circuit and the light-emission-OFF-time voltage drive circuit when light-emitting elements are all caused to emit light;

FIG. 7 is a timing chart illustrating light emission control performed for light-emitting elements in the light-emitting device of the exemplary embodiment; and

FIG. 8 illustrates an example of an output state table indicating the number of drive signals to be output in accordance with the number of light-emitting elements to simultaneously emit light.

### DETAILED DESCRIPTION

An exemplary embodiment of the disclosure will be described below in detail with reference to the accompanying drawings.

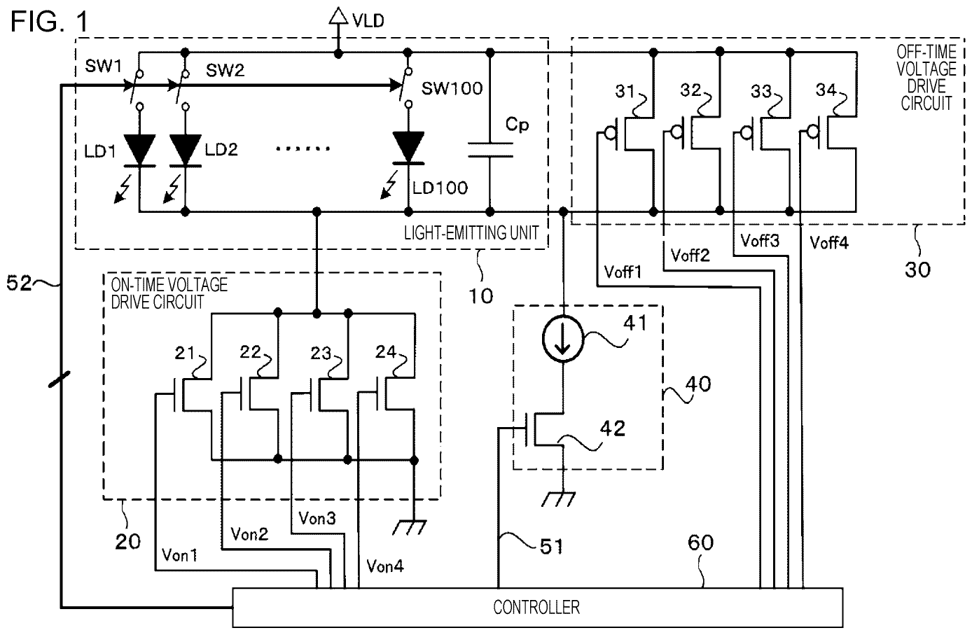

FIG. 1 is a circuit diagram illustrating the configuration of a light-emitting device according to the exemplary embodiment.

As illustrated in FIG. 1, the light-emitting device includes a light-emitting unit 10, a light-emission-ON-time voltage drive circuit 20 (hereinafter simply called the ON-time voltage drive circuit 20), a light-emission-OFF-time voltage drive circuit 30 (hereinafter simply called the OFF-time voltage drive circuit 30), a constant-current drive circuit 40, and a controller 60. The light-emitting device of the exemplary embodiment is used as a light source of a time-of-flight (TOF) sensor, for example.

The light-emitting unit 10 is constituted by a vertical cavity surface emitting laser (VCSEL) and includes multiple light-emitting elements LD1 through LD100. In the following description, the light-emitting elements LD1 through LD100 will be called the light-emitting elements LD unless it is necessary to distinguish them from each other. Switch elements SW1 through SW100 are respectively provided for the light-emitting elements LD1 through LD100. With the provision of the switch elements SW1 through SW100, the light-emitting unit 10 can perform control so that only light-emitting elements LD selected from among the light-emitting elements LD1 through LD100 emit light. In the light-emitting unit 10, parasitic capacitance Cp is generated in parallel with the light-emitting elements LD1 through LD100. Each of the cathode electrodes of the light-emitting elements LD1 through LD100 is connected to the ON-time voltage drive circuit 20. The anode electrodes of the light-emitting elements LD1 through LD100 are connected to a power supply voltage VLD via the respective switch elements SW1 through SW100.

The switch elements SW1 through SW100 are individually controlled by a switching signal 52 supplied from the controller 60 and each operate to cause the corresponding light-emitting element LD to emit light.

In the exemplary embodiment, 100 light-emitting elements LD1 through LD100 are provided. However, the number of light-emitting elements LD in the light-emitting unit 10 is not limited to 100, and several hundreds of light-emitting elements LD may be provided.

The ON-time voltage drive circuit 20 is constituted by four NMOS transistors 21 through 24 each disposed between the cathode electrodes of the light-emitting elements LD1 through LD100 and a ground potential. Driving signals Von1 through Von4 are respectively input into the gate electrodes of the NMOS transistors 21 through 24. The drain electrodes of the NMOS transistors 21 through 24 are each connected to the cathode electrodes of the light-emitting elements LD1 through LD100. The source electrodes of the NMOS transistors 21 through 24 are each connected to the ground potential.

The ON-time voltage drive circuit 20 serves to reduce the rise time of a light pulse waveform, which is the waveform of a light-emission current to flow when the light-emitting elements LD1 through LD100 emit light.

The OFF-time voltage drive circuit 30 is constituted by four PMOS transistors 31 through 34 each provided between the anode electrodes of the light-emitting elements LD1 through LD100 and the cathode electrodes thereof. Driving signals Voff1 through Voff4 are respectively input into the gate electrodes of the PMOS transistors 31 through 34. The drain electrodes of the PMOS transistors 31 through 34 are each connected to the cathode electrodes of the light-emitting elements LD1 through LD100. The source electrodes of the PMOS transistors 31 through 34 are each connected to the anode electrodes of the light-emitting elements LD1 through LD100.

The OFF-time voltage drive circuit 30 serves to reduce the fall time of the waveform of a light pulse wave to be applied to the light-emitting elements LD1 through LD100.

The constant-current drive circuit 40 is constituted by a constant-current source 41 and an NMOS transistor 42. A light-emission pulse signal 51 supplied from the controller 60 is input into the gate electrode of the NMOS transistor 42. The source electrode of the NMOS transistor 42 is connected to a ground potential. The drain electrode of the NMOS transistor 42 is connected to all the cathode electrodes of the light-emitting elements LD1 through LD100 via the constant-current source 41. The NMOS transistor 42 serves to cause a current to flow through the light-emitting elements LD1 through LD100 and to allow them to emit light as a result of being turned ON.

In the constant-current drive circuit 40 configured as described above, when the NMOS transistor 42 is turned ON, a current from the constant-current source 41 flows through light-emitting elements LD selected to emit light among the light-emitting elements LD1 through LD100. The constant-current source 41 can be implemented by a current mirror circuit, for example.

The ON-time voltage drive circuit 20, the OFF-time voltage drive circuit 30, and the constant-current drive circuit 40 form a drive circuit for driving the light-emitting elements LD1 through LD100.

The controller 60 selects light-emitting elements LD to emit light by using the switching signal 52 so as to switch between the light-emitting elements LD1 through LD100. The controller 60 also outputs the light-emission pulse signal 51 having a high level for a predetermined time so that the NMOS transistor 42 is turned ON for the predetermined time to cause the selected light-emitting elements LD to emit light. The controller 60 also controls the ON-time voltage drive circuit 20 so that the NMOS transistors selected from among the NMOS transistors 21 through 24 are turned ON at a timing when the selected light-emitting elements LD start emitting light. The number of NMOS transistors to be turned ON is determined in accordance with the number of light-emitting elements LD to simultaneously emit light. The number of light-emitting elements LD to simultaneously emit light is the number of light-emitting elements LD that are caused to simultaneously emit light among the light-emitting elements LD1 through LD100. The controller 60 also controls the OFF-time voltage drive circuit 30 so that the PMOS transistors selected from among the PMOS transistors 31 through 34 are turned ON at a timing when the selected light-emitting elements LD stop emitting light. The number of PMOS transistors to be turned ON is determined by the number of light-emitting elements LD to simultaneously emit light. More specifically, the controller 60 controls the ON-time voltage drive circuit 20 so that, as the number of light-emitting elements LD to simultaneously emit light is greater, the number of NMOS transistors to be turned ON selected from the NMOS transistors 21 through 24 becomes smaller. The controller 60 controls the OFF-time voltage drive circuit 30 so that, as the number of light-emitting elements LD to simultaneously emit light is greater, the number of PMOS transistors to be turned ON selected from the PMOS transistors 31 through 34 becomes smaller.

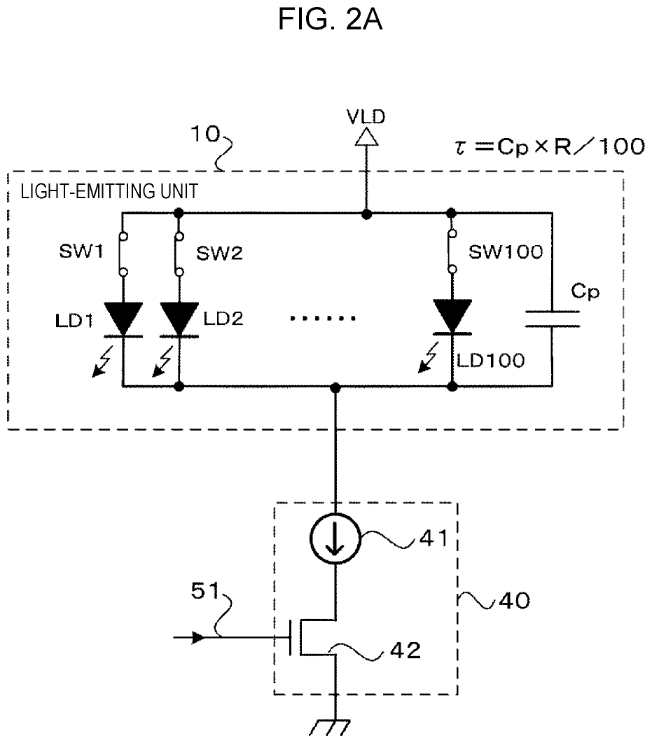

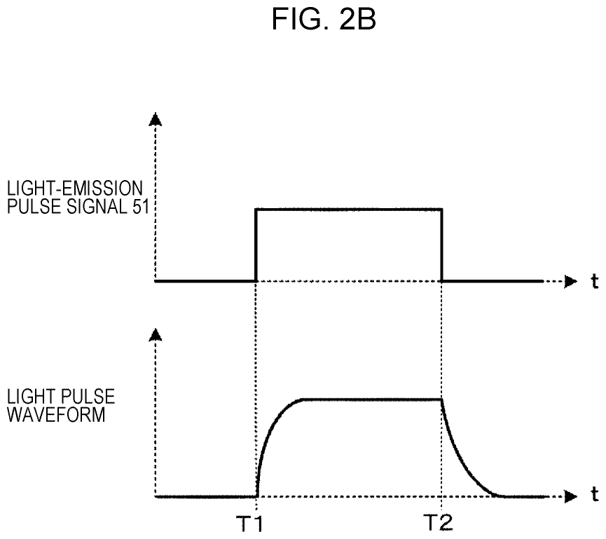

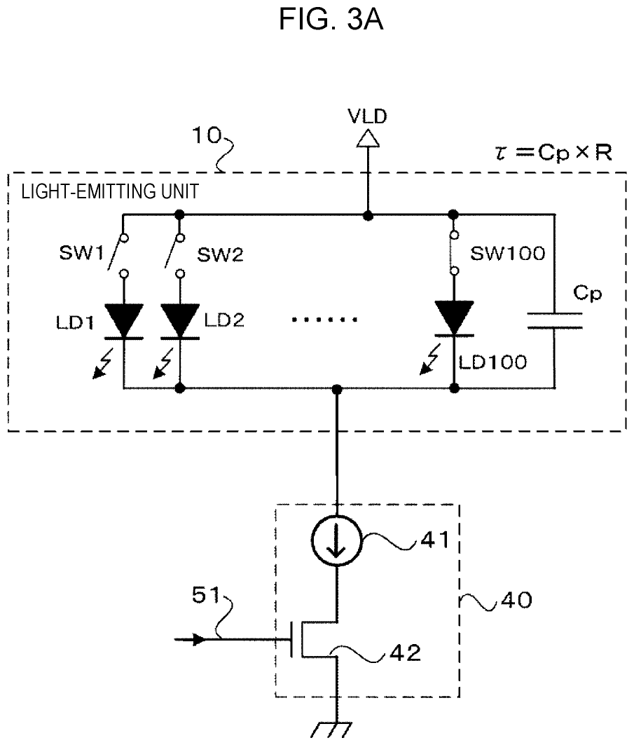

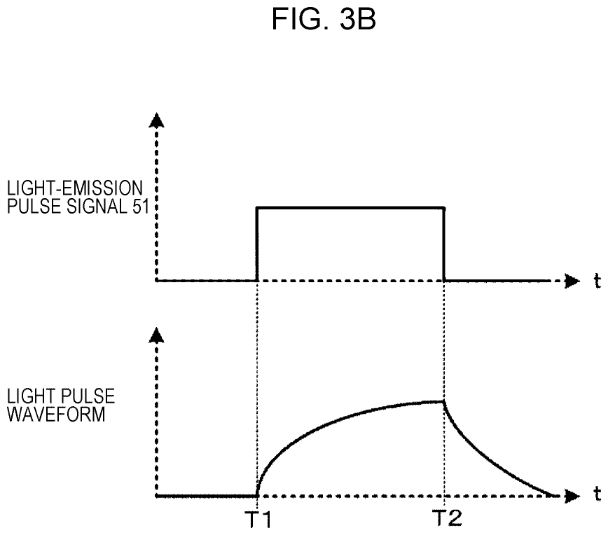

The reason why the ON-time voltage drive circuit 20 and the OFF-time voltage drive circuit 30 are provided will be explained below with reference to FIGS. 2A through 3B. FIGS. 2A through 3B show a case in which the light emission of the light-emitting unit 10 is controlled only by the constant-current drive circuit 40 without using the ON-time voltage drive circuit 20 and the OFF-time voltage drive circuit 30.

FIGS. 2A and 2B illustrate a case in which all the light-emitting elements LD1 through LD100 are caused to emit light. FIG. 2A is a circuit diagram illustrating the configuration in which all the light-emitting elements LD1 through LD100 emit light.

In the light-emitting unit 10 constituted by a VCSEL, the series resistance of each of the light-emitting elements LD1 through LD100 is relatively high. When, however, among the light-emitting elements LD1 through LD100, a large number of light-emitting elements LD are caused to simultaneously emit light, the combined resistance of the individual series resistance values becomes relatively low. For example, it is now assumed that the series resistance of one light-emitting element LD is 100Ω. In this case, when the 100 light-emitting elements LD1 through LD100 are all caused to emit light, the combined resistance becomes one-hundredth of 100Ω, that is, 1Ω.

As discussed above, the parasitic capacitance Cp is generated in the light-emitting unit 10. Hence, when a light-emission current flows through the light-emitting elements LD1 through LD100 by the constant-current drive circuit 40, waveform rounding occurs at the rising and the falling of the waveform of the light-emission current by the amount equal to the time constant of a CR circuit constituted by the combined resistance of the series resistance values and the parasitic capacitance Cp. For example, when the series resistance of one light-emitting element LD is indicated by R, the time constant τ of the CR circuit is expressed by the following equation (1).

τ=Cp×R/100 (1)

As a result, when the light-emission pulse signal 51 having a rectangular waveform is applied to the gate electrode of the NMOS transistor 42 of the constant-current drive circuit 40, waveform rounding occurs at the rising and the falling of the waveform of a light pulse wave, which is the waveform of a light-emission current flowing through the light-emitting elements LD1 through LD100, as shown in FIG. 2B.

Nevertheless, when the 100 light-emitting elements LD1 through LD100 are all caused to emit light, the combined resistance is about 1Ω and the time constant τ does not become considerably high. The waveform of the light-emission pulse wave applied to the light-emitting elements LD which are to emit light does not significantly deviate from a rectangular waveform.

The series resistance of the light-emitting elements LD which are to emit light greatly varies depending on the number of light-emitting elements LD to simultaneously emit light. FIGS. 3A and 3B illustrate a case in which, among the light-emitting elements LD1 through LD100, the light-emitting element LD100 is only caused to emit light. FIG. 3A is a circuit diagram illustrating the configuration in which the light-emitting element LD100 is only caused to emit light.

When only one light-emitting element LD, that is, the light-emitting element LD100, is caused to emit light, as shown in FIG. 3A, the combined resistance of the series resistance values results in 100Ω. In this case, the time constant τ of the CR circuit is expressed by the following equation (2).

τ=Cp×R (2)

That is, the time constant τ when the light-emitting element LD100 only emits light is 100 times as large as that when all the light-emitting elements LD1 through LD100 emit light.

As a result, as shown in FIG. 3B, when the light-emission pulse signal 51 having a rectangular waveform is applied to the gate electrode of the NMOS transistor 42 of the constant-current drive circuit 40, a large amount of waveform rounding occurs at the rising and the falling of the waveform of a light pulse wave, which is the waveform of a light-emission current to flow through the light-emitting element LD100. That is, the waveform of the light pulse wave applied to the light-emitting element LD100 significantly deviates from the rectangular waveform. Causing the waveform of the light pulse wave applied to the light-emitting element LD to significantly deviate from the rectangular waveform may fail to achieve a high switching speed for causing the light-emitting element LD to emit light, which may make the operation of the light-emitting device slow.

To make the rising and falling transitions of a light pulse waveform easier and smoother when a small number of light-emitting elements LD is cause to simultaneously emit light, the ON-time voltage drive circuit and the OFF-time voltage drive circuit are provided.

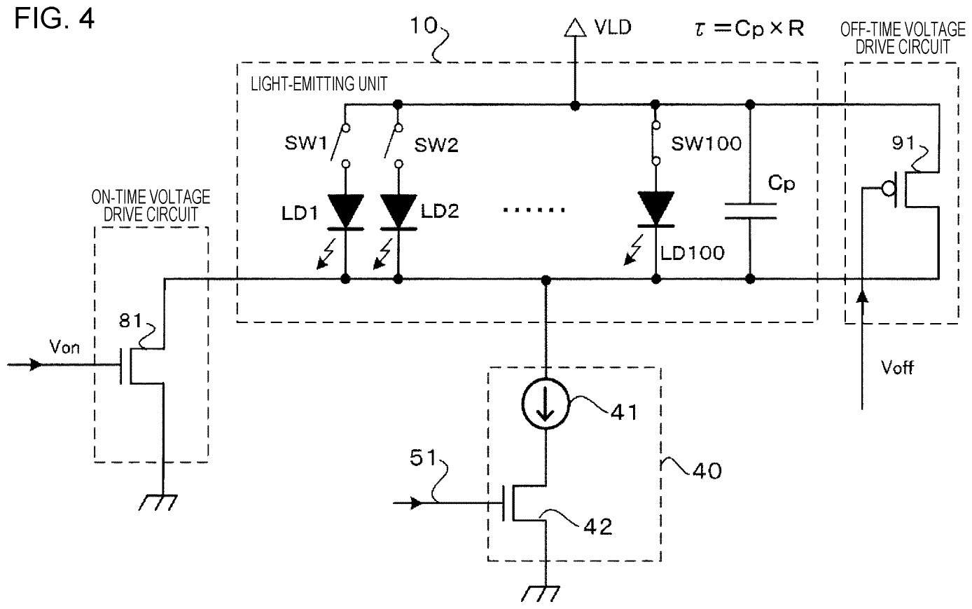

FIG. 4 is a circuit diagram of the configuration in which the ON-time voltage drive circuit and the OFF-time voltage drive circuit are each constituted by one transistor. In FIG. 4, one NMOS transistor 81 forms the ON-time voltage drive circuit, while one PMOS transistor 91 forms the OFF-time voltage drive circuit. The ON-time voltage drive circuit drives the voltage when a light pulse waveform rises so as to intentionally charge the parasitic capacitance Cp, thereby making the rising transition of the light pulse waveform easier and smoother. The OFF-time voltage drive circuit drives the voltage when a light pulse waveform falls so as to intentionally discharge the parasitic capacitance Cp, thereby making the falling transition of the light pulse waveform easier and smoother.

In the ON-time voltage drive circuit in FIG. 4, a drive signal Von is applied to the gate electrode of the NMOS transistor 81. The drive signal Von is made to have a high level (hereinafter abbreviated as the H level), so that the NMOS transistor 81 is turned ON to facilitate the charging of the parasitic capacitance Cp. In the OFF-time voltage drive circuit in FIG. 4, a drive signal Voff is applied to the gate electrode of the PMOS transistor 91. The drive signal Voff is made to have a low level (hereinafter abbreviated as the L level), so that the PMOS transistor 91 is turned ON to facilitate the discharging of the parasitic capacitance Cp. Since the OFF-time voltage drive circuit is constituted by the PMOS transistor 91, the drive signal Voff is a low active signal.

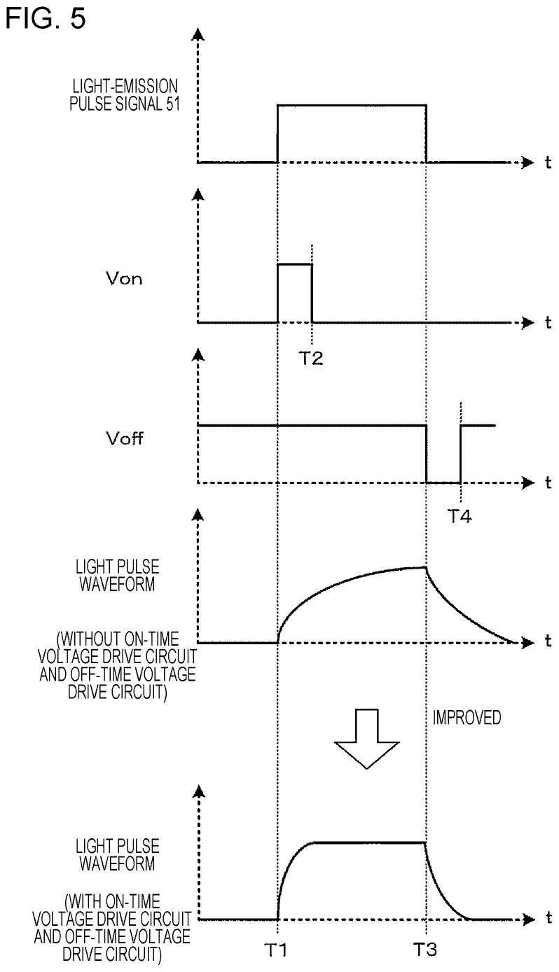

FIG. 5 is a timing chart illustrating that a light pulse waveform becomes similar to a rectangular waveform by the provision of the ON-time voltage drive circuit and the OFF-time voltage drive circuit shown in FIG. 4.

As illustrated in FIG. 5, when the light-emission pulse signal 51 is changed to the H level at time T1, the drive signal Von is also changed to the H level at time T1. The drive signal Von then falls to the L level at time T2 after the lapse of a predetermined period after time T1. The light-emission pulse signal 51 is changed to the L level at time T3, and the drive signal Voff is also changed to the L level at time T3. The drive signal Voff is then made to have the H level at time T4 after the lapse of a predetermined period after time T3.

As is seen from FIG. 5, the rising and falling transitions of the light pulse waveform are made easier and smoother by the provision of the ON-time voltage drive circuit and the OFF-time voltage drive circuit, and the light pulse waveform, which significantly deviates from the rectangular waveform without the ON-time voltage drive circuit and the OFF-time voltage drive circuit, becomes similar to the rectangular waveform.

As stated above, however, the combined resistance of the light-emitting elements LD1 through LD100 greatly varies depending on the number of light-emitting elements LD which are caused to simultaneously emit light. How much the light pulse waveform can become similar to the rectangular waveform is determined by the device size of the NMOS transistor 81 and that of the PMOS transistor 91. To make the light pulse waveform similar to the rectangular waveform, if the device size of the NMOS transistor 81 and that of the PMOS transistor 91 are determined when only one light-emitting element emits light, a desirable waveform of the light pulse wave may not be obtained when more light-emitting elements LD are caused to simultaneously emit light.

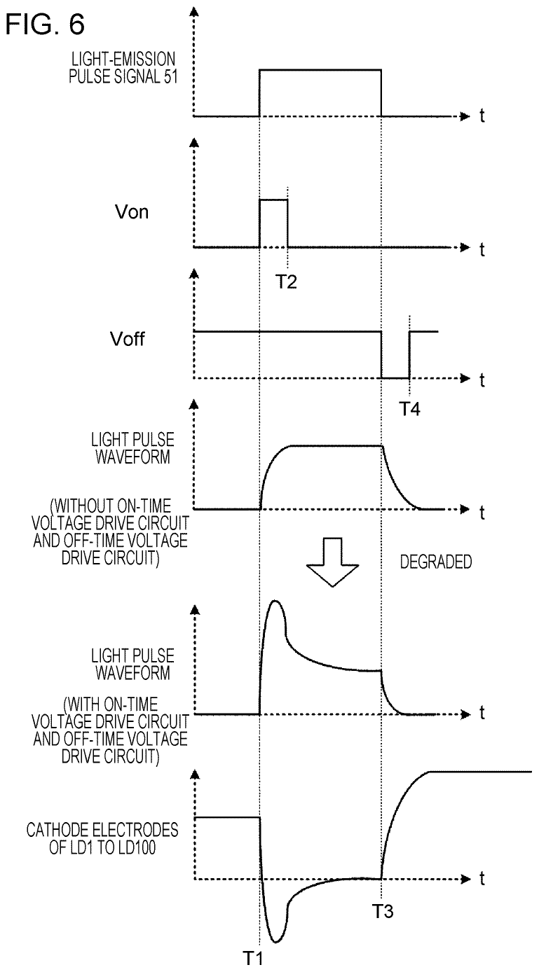

It is now assumed that the device size of the NMOS transistor 81 and that of the PMOS transistor 91 are determined to have a desirable light pulse waveform when only one light-emitting element emits light. FIG. 6 is a timing chart illustrating how much a light pulse waveform becomes similar to a rectangular waveform when all the light-emitting elements LD1 through LD100 are caused to emit light.

FIG. 6 shows that the rising and falling transitions are excessively facilitated by the provision of the ON-time voltage drive circuit and the OFF-time voltage drive circuit so that overshooting occurs at the rising of the light pulse waveform. The light pulse waveform is not improved; on the contrary, it significantly deviates from the rectangular waveform. Additionally, the voltage of the cathode electrodes of the light-emitting elements LD1 through LD100 soars by the OFF-time voltage drive circuit which is activated at time T3. Because of such a voltage rise of the cathode electrodes, the light-emitting elements LD1 through LD100 are unable to smoothly start emitting light when the light-emission pulse signal 51 is changed to the H level next time.

As illustrated in FIG. 6, when all the light-emitting elements LD1 through LD100 emit light, the light pulse waveform becomes more similar to the rectangular waveform without the ON-time voltage drive circuit and the OFF-time voltage drive circuit. In contrast, the light pulse waveform is degraded and significantly deviates from the rectangular waveform with the ON-time voltage drive circuit and the OFF-time voltage drive circuit.

To address the above-described issue, in the light-emitting device of the exemplary embodiment, the ON-time voltage drive circuit 20 and the OFF-time voltage drive circuit 30 shown in FIG. 1 are used so that the waveform of the light pulse wave to be applied to the light-emitting elements LD which are to emit light become similar to the rectangular waveform even when the number of light-emitting elements LD to simultaneously emit light among the light-emitting elements LD1 through LD100 is changed.

The device size of each of the NMOS transistors 21 through 24 in the ON-time voltage drive circuit 20 is about ¼ of that of the NMOS transistor 81 of the ON-time voltage drive circuit shown in FIG. 4. That is, the state in which the four NMOS transistors 21 through 24 are ON at the same time is substantially equivalent to that in which the NMOS transistor 81 is ON.

Likewise, the device size of each of the PMOS transistors 31 through 34 in the OFF-time voltage drive circuit 30 is about ¼ of that of the PMOS transistor 91 of the OFF-time voltage drive circuit shown in FIG. 4. That is, the state in which the four PMOS transistors 31 through 34 are ON at the same time is substantially equivalent to that in which the PMOS transistor 91 is ON.

When, in the exemplary embodiment, the controller 60 outputs the light-emission pulse signal 51 to the constant-current drive circuit 40 to cause light-emitting elements LD to emit light, it switches the number of drive signals Von1 through Von4 and the number of drive signals Voff1 through Voff4 to be output in accordance with the number of light-emitting elements LD to simultaneously emit light.

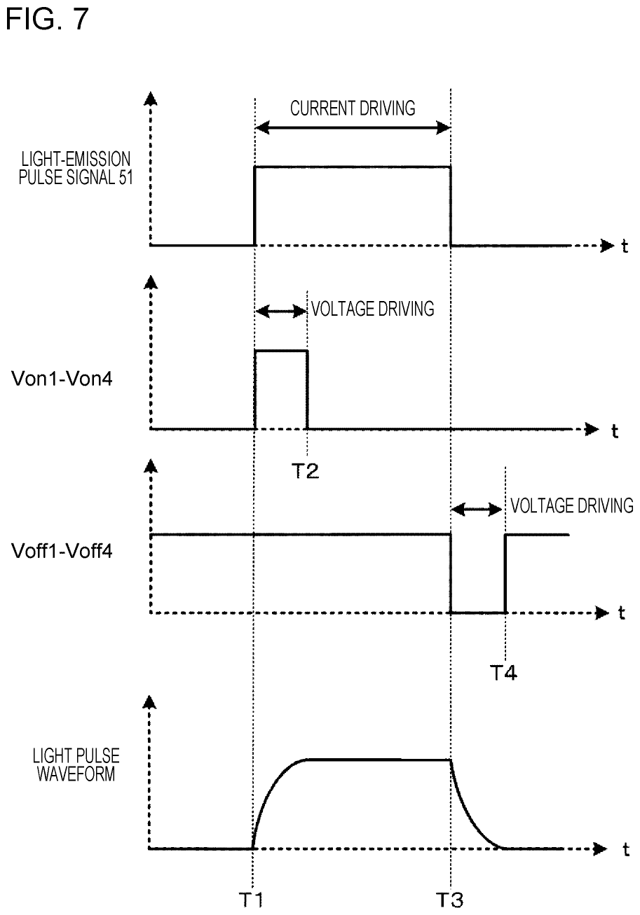

FIG. 7 is a timing chart illustrating the light emission control performed for the light-emitting elements LD in the light-emitting device in the exemplary embodiment.

As illustrated in FIG. 7, when the light-emission pulse signal 51 is changed to the H level at time T1, the drive signals Von1 through Von4 are also changed to the H level at time T1. The drive signals Von1 through Von4 then fall to the L level at time T2 after the lapse of a predetermined period after time T1. Then, when the light-emission pulse signal 51 is changed to the L level at time T3, the drive signals Voff1 through Voff4 are also switched to the L level, which is the active level, at time T3. The drive signals Voff1 through Voff4 are then changed to the H level at time T4 after the lapse of a predetermined period after time T3.

For the period until time T1, the light-emitting elements LD are OFF, that is, they do not emit light.

During the period from time T1 to time T2, in synchronization with the rising of the light-emission pulse signal 51, the NMOS transistor 42 is turned ON to drive the current, and also, the NMOS transistors 21 through 24 are turned ON to drive the voltage. How much the rising transition of the waveform of the light-emission pulse signal 51 is facilitated by the voltage driving during this period is determined by the number of drive signals to be output among the drive signals Von1 through Von4.

During the period from time T2 to time T3, the drive signals Von1 through Von4 are at the L level so that the voltage driving is not performed, but the constant current driving is performed.

During the period from time T3 to time T4, in synchronization with the falling of the light-emission pulse signal 51, the constant current driving has stopped and the PMOS transistors 31 through 34 are turned ON so that the voltage driving is restarted. How much the falling transition of the waveform of the light-emission pulse signal 51 is facilitated by the voltage driving during this period is determined by the number of drive signals to be output among the drive signals Voff1 through Voff4.

At time T4, the drive signals Voff1 through Voff4 are switched to the H level so that the light-emitting elements LD stop emitting light.

As a result of repeating the above-described operation, the light-emitting elements LD repeatedly start emitting light and stop emitting light.

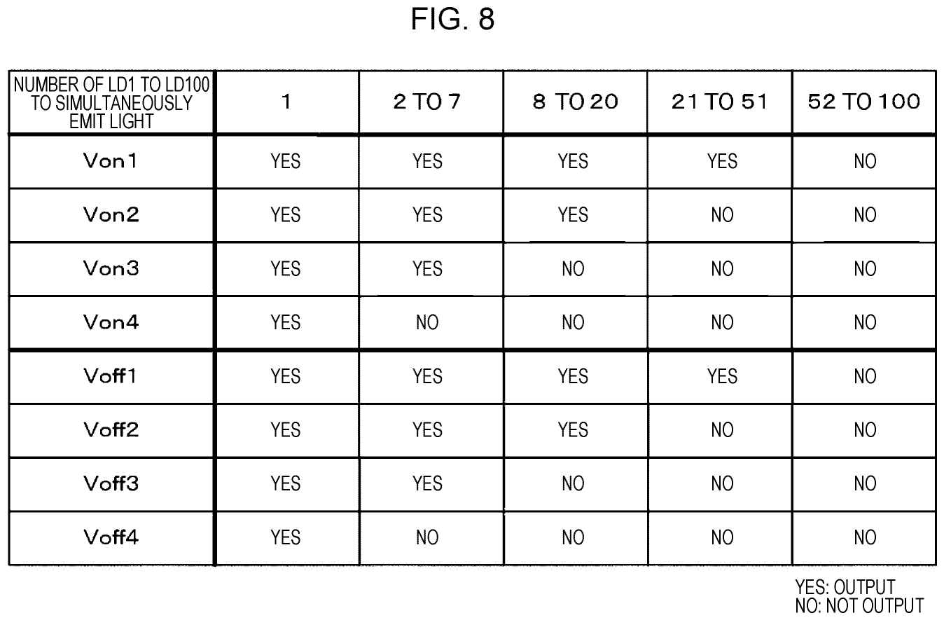

As discussed above, in the exemplary embodiment, the controller 60 switches the number of drive signals to be output among the drive signals Von1 through Von4 and the number of drive signals to be output among the drive signals Voff1 through Voff4 in accordance with the number of light-emitting elements LD to simultaneously emit light. The controller 60 switches the number of drive signals to be output, based on the output state table shown in FIG. 8.

FIG. 8 illustrates an example of the output state table indicating the number of drive signals Von1 through Von4 and the number of the drive signals Voff1 through Voff4 to be output in accordance with the number of light-emitting elements LD to simultaneously emit light.

FIG. 8 shows that, when the number of light-emitting elements LD to simultaneously emit light is one, the four drive signals Von1 through Von4 in the ON-time voltage drive circuit 20 are all output. That is, at the rising of the light pulse waveform, the four NMOS transistors 21 through 24 are all turned ON, so that the rising transition of the light pulse waveform is made easier and smoother. FIG. 8 also shows that, when the number of light-emitting elements LD to simultaneously emit light is one, the four drive signals Voff1 through Voff4 in the OFF-time voltage drive circuit 30 are all output. That is, at the falling of the light pulse waveform, the four PMOS transistors 31 through 34 are all turned ON, so that the falling transition of the light pulse waveform is made easier and smoother.

As the number of light-emitting elements LD to simultaneously emit light is greater, the number of drive signals to be output among the drive signals Von through Von4 and that of drive signals to be output among the drive signals Voff1 through Voff4 are set to be smaller. That is, the controller 60 controls the ON-time voltage drive circuit 20 so that, as the number of light-emitting elements LD to simultaneously emit light is greater, the number of NMOS transistors to be turned ON among the four NMOS transistors 21 through 24 becomes smaller. The controller 60 also controls the OFF-time voltage drive circuit 30 so that, as the number of light-emitting elements LD to simultaneously emit light is greater, the number of PMOS transistors to be turned ON among the four PMOS transistors 31 through 34 becomes smaller.

For example, when the number of light-emitting elements LD to simultaneously emit light is 52 to 100, the drive signals Von1 through Von4 and the drive signals Voff1 through Voff4 are not output. That is, in this case, the light-emitting elements LD are caused to emit light without activating the ON-time voltage drive circuit 20 and the OFF-time voltage drive circuit 30.

In the light-emitting device of the exemplary embodiment, the controller 60 performs control so that, as the number of light-emitting elements LD to simultaneously emit light is smaller, the rising and falling transitions of the light pulse waveform can be made easier and smoother by the ON-time voltage drive circuit 20 and the OFF-time voltage drive circuit 30. With this control operation, even when the number of light-emitting elements LD to simultaneously emit light is changed, the waveform of a light pulse to be applied to the light-emitting elements LD to emit light becomes similar to the rectangular waveform.

In the above-described exemplary embodiment, the constant-current drive circuit 40 is constituted by one constant-current source 41 and one NMOS transistor 42.

However, the NMOS transistor 42 may be replaced by multiple NMOS transistors having substantially the same device size. In this case, the controller 60 may control the constant-current drive circuit 40 so that, as the number of light-emitting elements LD to simultaneously emit light among the light-emitting elements LD1 through LD100 is greater, a larger number of NMOS transistors is turned ON.

As the number of light-emitting elements LD to simultaneously emit light is greater, a larger amount of light-emission current flows through the constant-current drive circuit 40. Hence, as the number of light-emitting elements LD to simultaneously emit light is greater, the amount of light-emission current to flow through the constant-current drive circuit 40 is set to be larger.

In another example, the NMOS transistor 42 may be replaced by multiple NMOS transistors having different device sizes. In this case, the controller 60 may control the constant-current drive circuit 40 so that, as the number of light-emitting elements LD to simultaneously emit light among the light-emitting elements LD1 through LD100 is greater, an NMOS transistor having a larger device size is turned ON among the NMOS transistors.

In the above-described exemplary embodiment, the ON-time voltage drive circuit 20 is constituted by the four NMOS transistors 21 through 24. However, the ON-time voltage drive circuit 20 may include only one NMOS transistor. In this case, the amount by which the rising transition of the light pulse waveform is facilitated becomes uniform, but the amount by which the falling transition of the light pulse waveform is facilitated is varied in accordance with the number of light-emitting elements LD to simultaneously emit light.

In the above-described exemplary embodiment, the OFF-time voltage drive circuit 30 is constituted by the four PMOS transistors 31 through 34. However, the OFF-time voltage drive circuit 30 may include only one PMOS transistor. In this case, the amount by which the falling transition of the light pulse waveform is facilitated becomes uniform, but the amount by which the rising transition of the light pulse waveform is facilitated is varied in accordance with the number of light-emitting elements LD to simultaneously emit light.

In the above-described exemplary embodiment, the number of NMOS transistors to be turned ON is determined by the number of light-emitting elements LD to simultaneously emit light, and the number of PMOS transistors to be turned ON is determined by the number of light-emitting elements LD to simultaneously emit light. However, only one of the number of NMOS transistors to be turned ON and the number of PMOS transistors to be turned ON may be determined by the number of light-emitting elements LD to simultaneously emit light.

The foregoing description of the exemplary embodiments of the present disclosure has been provided for the purposes of illustration and description. It is not intended to be exhaustive or to limit the disclosure to the precise forms disclosed. Obviously, many modifications and variations will be apparent to practitioners skilled in the art. The embodiments were chosen and described in order to best explain the principles of the disclosure and its practical applications, thereby enabling others skilled in the art to understand the disclosure for various embodiments and with the various modifications as are suited to the particular use contemplated. It is intended that the scope of the disclosure be defined by the following claims and their equivalents.

### APPENDIX

(((1)))

A light-emitting device comprising:
a light-emitting unit including a plurality of light-emitting elements;
a drive circuit that serves to drive the plurality of light-emitting elements and includes
   a plurality of first transistors each provided between cathode electrodes of the plurality of light-emitting elements and a ground potential,
   a plurality of second transistors each provided between anode electrodes of the plurality of light-emitting elements and the cathode electrodes of the plurality of light-emitting elements, and
   a third transistor that serves to cause a current to flow through the plurality of light-emitting elements to allow the plurality of light-emitting elements to emit light as a result of the third transistor being turned ON; and
a controller that selects at least one light-emitting element which is caused to emit light among the plurality of light-emitting elements so as to switch between the plurality of light-emitting elements and causes the third transistor to be ON for a predetermined period so that the selected at least one light-emitting element emits light, and that controls the drive circuit so that at least one first transistor of the plurality of first transistors is turned ON at a timing when the selected at least one light-emitting element starts emitting light, the number of the at least one first transistor being determined in accordance with the number of the selected at least one light-emitting element which is to simultaneously emit light, and/or so that at least one second transistor of the plurality of second transistors is turned ON at a timing when the selected at least one light-emitting element stops emitting light, the number of the at least one second transistor being determined in accordance with the number of the selected at least one light-emitting element which is to simultaneously emit light,
wherein the controller controls the drive circuit so that, as the number of the selected at least one light-emitting element which is to simultaneously emit light is greater, the number of the at least one first transistor to be turned ON becomes smaller and the number of the at least one second transistor to be turned ON becomes smaller.
   (((2)))

A light-emitting device comprising:
a light-emitting unit including a plurality of light-emitting elements;
a drive circuit that serves to drive the plurality of light-emitting elements and includes
   a plurality of first transistors each provided between cathode electrodes of the plurality of light-emitting elements and a ground potential,
   a second transistor provided between anode electrodes of the plurality of light-emitting elements and the cathode electrodes of the plurality of light-emitting elements, and
   a third transistor that serves to cause a current to flow through the plurality of light-emitting elements to allow the plurality of light-emitting elements to emit light as a result of the third transistor being turned ON; and
a controller that selects at least one light-emitting element which is caused to emit light among the plurality of light-emitting elements so as to switch between the plurality of light-emitting elements and causes the third transistor to be ON for a predetermined period so that the selected at least one light-emitting element emits light, and that controls the drive circuit so that at least one first transistor of the plurality of first transistors is turned ON at a timing when the selected at least one light-emitting element starts emitting light, the number of the at least one first transistor being determined in accordance with the number of the selected at least one light-emitting element which is to simultaneously emit light, and so that the second transistor is turned ON at a timing when the selected at least one light-emitting element stops emitting light,
wherein the controller controls the drive circuit so that, as the number of the selected at least one light-emitting element which is to simultaneously emit light is greater, the number of the at least one first transistor to be turned ON becomes smaller.
   (((3)))

A light-emitting device comprising:
a light-emitting unit including a plurality of light-emitting elements;
a drive circuit that serves to drive the plurality of light-emitting elements and includes
   a first transistor provided between cathode electrodes of the plurality of light-emitting elements and a ground potential,
   a plurality of second transistors each provided between anode electrodes of the plurality of light-emitting elements and the cathode electrodes of the plurality of light-emitting elements, and
   a third transistor that serves to cause a current to flow through the plurality of light-emitting elements to allow the plurality of light-emitting elements to emit light as a result of the third transistor being turned ON; and
a controller that selects at least one light-emitting element which is caused to emit light among the plurality of light-emitting elements so as to switch between the plurality of light-emitting elements and causes the third transistor to be ON for a predetermined period so that the selected at least one light-emitting element emits light, and that controls the drive circuit so that the first transistor is turned ON at a timing when the selected at least one light-emitting element starts emitting light and so that at least one second transistor of the plurality of second transistors is turned ON at a timing when the selected at least one light-emitting element stops emitting light, the number of the at least one second transistor being determined in accordance with the number of the selected at least one light-emitting element which is to simultaneously emit light,
wherein the controller controls the drive circuit so that, as the number of the selected at least one light-emitting element which is to simultaneously emit light is greater, the number of the at least one second transistor to be turned ON becomes smaller.
   (((4)))

The light-emitting device according to one of (((1))) to (((3))), wherein:
the plurality of first transistors or the first transistor form a first voltage drive circuit that serves to reduce a rise time of a light pulse waveform, the light pulse waveform being a waveform of a light-emission current to flow when the plurality of light-emitting elements emit light; and
the plurality of second transistors or the second transistor form a second voltage drive circuit that serves to reduce a fall time of the light pulse waveform.
   (((5)))

The light-emitting device according to one of (((1))) to (((4))), wherein:
the drive circuit further includes a constant-current source; and
the constant-current source and the third transistor form a constant-current drive circuit that serves to cause a current to flow from the constant-current source to the selected at least one light-emitting element as result of the third transistor being turned ON.
   (((6)))

The light-emitting device according to (((5))), wherein:
the third transistor includes a plurality of NMOS transistors having a substantially identical device size; and
the controller controls the drive circuit so that, as the number of the selected at least one light-emitting element which is to simultaneously emit light is greater, a larger number of NMOS transistors among the plurality of NMOS transistors is turned ON.
   (((7)))

The light-emitting device according to (((5))), wherein:
the third transistor includes a plurality of NMOS transistors having different device sizes; and
the controller controls the drive circuit so that, as the number of the selected at least one light-emitting element which is to simultaneously emit light is greater, an NMOS transistor having a larger device size among the plurality of NMOS transistors is turned ON.

What is claimed is:

1. A light-emitting device comprising:
a light-emitting unit including a plurality of light-emitting elements;
a drive circuit that serves to drive the plurality of light-emitting elements and includes
a plurality of first transistors each provided between cathode electrodes of the plurality of light-emitting elements and a ground potential,
a plurality of second transistors each provided between anode electrodes of the plurality of light-emitting elements and the cathode electrodes of the plurality of light-emitting elements, and
a third transistor that serves to cause a current to flow through the plurality of light-emitting elements to allow the plurality of light-emitting elements to emit light as a result of the third transistor being turned ON; and
a controller that selects at least one light-emitting element which is caused to emit light among the plurality of light-emitting elements so as to switch between the plurality of light-emitting elements and causes the third transistor to be ON for a predetermined period so that the selected at least one light-emitting element emits light, and that controls the drive circuit so that at least one first transistor of the plurality of first transistors is turned ON at a timing when the selected at least one light-emitting element starts emitting light, the number of the at least one first transistor being determined in accordance with the number of the selected at least one light-emitting element which is to simultaneously emit light, and/or so that at least one second transistor of the plurality of second transistors is turned ON at a timing when the selected at least one light-emitting element stops emitting light, the number of the at least one second transistor being determined in accordance with the number of the selected at least one light-emitting element which is to simultaneously emit light,
wherein the controller controls the drive circuit so that, as the number of the selected at least one light-emitting element which is to simultaneously emit light is greater, the number of the at least one first transistor to be turned ON becomes smaller and the number of the at least one second transistor to be turned ON becomes smaller.

2. A light-emitting device comprising:
a light-emitting unit including a plurality of light-emitting elements;
a drive circuit that serves to drive the plurality of light-emitting elements and includes
a plurality of first transistors each provided between cathode electrodes of the plurality of light-emitting elements and a ground potential,
a second transistor provided between anode electrodes of the plurality of light-emitting elements and the cathode electrodes of the plurality of light-emitting elements, and
a third transistor that serves to cause a current to flow through the plurality of light-emitting elements to allow the plurality of light-emitting elements to emit light as a result of the third transistor being turned ON; and
a controller that selects at least one light-emitting element which is caused to emit light among the plurality of light-emitting elements so as to switch between the plurality of light-emitting elements and causes the third transistor to be ON for a predetermined period so that the selected at least one light-emitting element emits light, and that controls the drive circuit so that at least one first transistor of the plurality of first transistors is turned ON at a timing when the selected at least one light-emitting element starts emitting light, the number of the at least one first transistor being determined in accordance with the number of the selected at least one light-emitting element which is to simultaneously emit light, and so that the second transistor is turned ON at a timing when the selected at least one light-emitting element stops emitting light,
wherein the controller controls the drive circuit so that, as the number of the selected at least one light-emitting element which is to simultaneously emit light is greater, the number of the at least one first transistor to be turned ON becomes smaller.

3. A light-emitting device comprising:
a light-emitting unit including a plurality of light-emitting elements;
a drive circuit that serves to drive the plurality of light-emitting elements and includes
a first transistor provided between cathode electrodes of the plurality of light-emitting elements and a ground potential,
a plurality of second transistors each provided between anode electrodes of the plurality of light-emitting elements and the cathode electrodes of the plurality of light-emitting elements, and
a third transistor that serves to cause a current to flow through the plurality of light-emitting elements to allow the plurality of light-emitting elements to emit light as a result of the third transistor being turned ON; and
a controller that selects at least one light-emitting element which is caused to emit light among the plurality of light-emitting elements so as to switch between the plurality of light-emitting elements and causes the third transistor to be ON for a predetermined period so that the selected at least one light-emitting element emits light, and that controls the drive circuit so that the first transistor is turned ON at a timing when the selected at least one light-emitting element starts emitting light and so that at least one second transistor of the plurality of second transistors is turned ON at a timing when the selected at least one light-emitting element stops emitting light, the number of the at least one second transistor being determined in accordance with the number of the selected at least one light-emitting element which is to simultaneously emit light,
wherein the controller controls the drive circuit so that, as the number of the selected at least one light-emitting element which is to simultaneously emit light is greater, the number of the at least one second transistor to be turned ON becomes smaller.

4. The light-emitting device according to claim 1, wherein:
the plurality of first transistors form a first voltage drive circuit that serves to reduce a rise time of a light pulse waveform, the light pulse waveform being a waveform of a light-emission current to flow when the plurality of light-emitting elements emit light; and
the plurality of second transistors form a second voltage drive circuit that serves to reduce a fall time of the light pulse waveform.

5. The light-emitting device according to claim 2, wherein:
the plurality of first transistors form a first voltage drive circuit that serves to reduce a rise time of a light pulse waveform, the light pulse waveform being a waveform of a light-emission current to flow when the plurality of light-emitting elements emit light; and
the second transistor forms a second voltage drive circuit that serves to reduce a fall time of the light pulse waveform.

6. The light-emitting device according to claim 3, wherein:
the first transistor forms a first voltage drive circuit that serves to reduce a rise time of a light pulse waveform, the light pulse waveform being a waveform of a light-emission current to flow when the plurality of light-emitting elements emit light; and
the plurality of second transistors form a second voltage drive circuit that serves to reduce a fall time of the light pulse waveform.

7. The light-emitting device according to claim 1, wherein:
the drive circuit further includes a constant-current source; and
the constant-current source and the third transistor form a constant-current drive circuit that serves to cause a current to flow from the constant-current source to the selected at least one light-emitting element as result of the third transistor being turned ON.

8. The light-emitting device according to claim 7, wherein:
the third transistor includes a plurality of NMOS transistors having a substantially identical device size; and
the controller controls the drive circuit so that, as the number of the selected at least one light-emitting element which is to simultaneously emit light is greater, a larger number of NMOS transistors among the plurality of NMOS transistors is turned ON.

9. The light-emitting device according to claim 7, wherein:
the third transistor includes a plurality of NMOS transistors having different device sizes; and
the controller controls the drive circuit so that, as the number of the selected at least one light-emitting element which is to simultaneously emit light is greater, an NMOS transistor having a larger device size among the plurality of NMOS transistors is turned ON.
